(19) United States
(12) Patent Application Publication
(10) Pub. No.: US 2025/0136437 A1
(43) Pub. Date: May 1, 2025

(54) Membrane Device Fabrication

(71) Applicant: X-FAB Global Services GmbH, Erfurt (DE)

(72) Inventor: Yves Dufour, Fontainebleau (FR)

(21) Appl. No.: 18/918,598

(22) Filed: Oct. 17, 2024

(30) Foreign Application Priority Data
Oct. 25, 2023 (GB) 2316334.8

(51) Int. Cl. B81C 1/00

(52) U.S. Cl. CPC B81C 1/00158; B81C 2201/0132; B81C 2201/0147; B81C 2201/0174; B81C 2201/0198; B81C 2203/051

(57) ABSTRACT

A method of forming a membrane of a semiconductor membrane device is provided. The method includes providing a silicon on insulator (SOI) substrate having an active silicon layer, a buried oxide (BOX) layer, and a handle wafer. The method further includes determining a membrane area of said substrate, locally removing said BOX layer in at least a part of said membrane area, providing one or more dielectric layers on said active silicon layer, and etching said substrate to form said membrane that includes said one or more dielectric layers in said membrane area. Said etching includes an anisotropic etch through said handle wafer and said active silicon layer using an etch mask defining an etch area, and said etch area overlaps at least a part of said membrane area.

### CROSS-REFERENCE TO RELATED APPLICATIONS

This application claims priority to United Kingdom Patent Application No. GB2316334.8, titled “Membrane Device Fabrication,” having a filing date of Oct. 25, 2023, which is incorporated herein by reference in its entirety and for all purposes.

### TECHNICAL FIELD

The present invention relates to membrane device fabrication.

### BACKGROUND

Micro machined membrane devices are used in a variety of different technologies, such as sensor technology (e.g. pressure sensors), microphones, transducers and actuators. The membrane's performance is highly sensitive to the effective dimensions of the membrane and its placement versus other design features.

There is a continued need for improving the fabrication process for providing membrane devices.

### SUMMARY OF INVENTION

Aspects of the present invention provide methods of making a membrane device, such as a MEMS membrane device, as set out in the appended claims.

Preferred embodiments of the invention will now be described with reference to the accompanying drawings.

### BRIEF DESCRIPTION OF DRAWINGS

FIG. 1 shows a schematic cross section of a membrane device;

FIG. 2 shows a schematic cross section of another membrane device;

FIG. 3 shows a schematic cross section of a further membrane device;

FIG. 4 shows a schematic cross section of a further membrane device;

FIG. 5 shows a schematic cross section of an apparatus comprising an array of membrane devices;

FIG. 6A to 6E show the steps of a method of forming a membrane device;

FIG. 7 shows a schematic cross section of a further membrane device;

FIG. 8A to 8F show the steps of another method of forming a membrane device

FIG. 9A to 9D shows the steps of part of a method of forming a membrane device.

### DETAILED DESCRIPTION

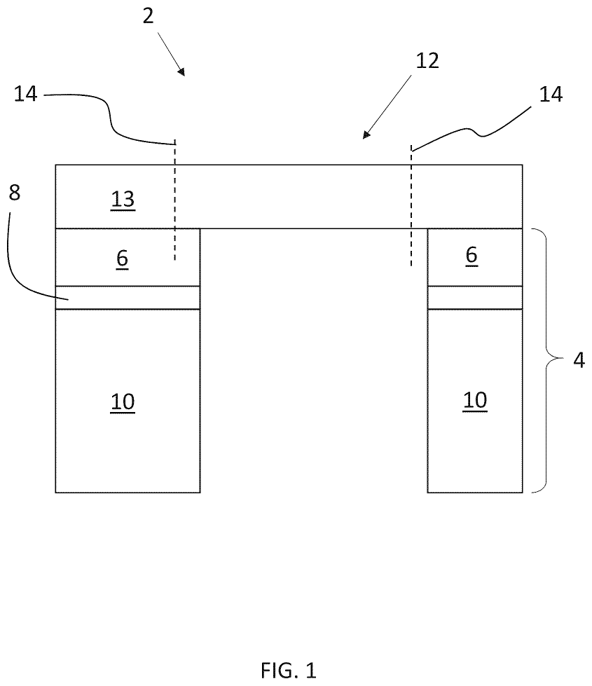

FIG. 1 shows a membrane device 2 comprising a SOI substrate 4 comprising an active silicon layer 6, a buried oxide (BOX) layer 8 and a handle wafer 10 (comprising silicon). A membrane 12 is formed from one or more dielectric layers (typically SiO₂) 13, and is defined by an opening in the active silicon layer 6. To form the membrane, the substrate can be etched from the back (the side of the handle wafer 10), changing the type of etching for the BOX layer 8. It can be difficult to align a back side etch with front side features, which increases the tolerances on the membrane location. The dashed lines 14 indicate the intended/nominal membrane area, whereby the (actual) membrane 12 is offset from the nominal membrane area due to these tolerances. Furthermore, the handle wafer 10 has relatively great thickness (e.g. >400 μm), and even a small sidewall angle can have a significant effect on the final membrane dimensions and thereby increase the tolerances.

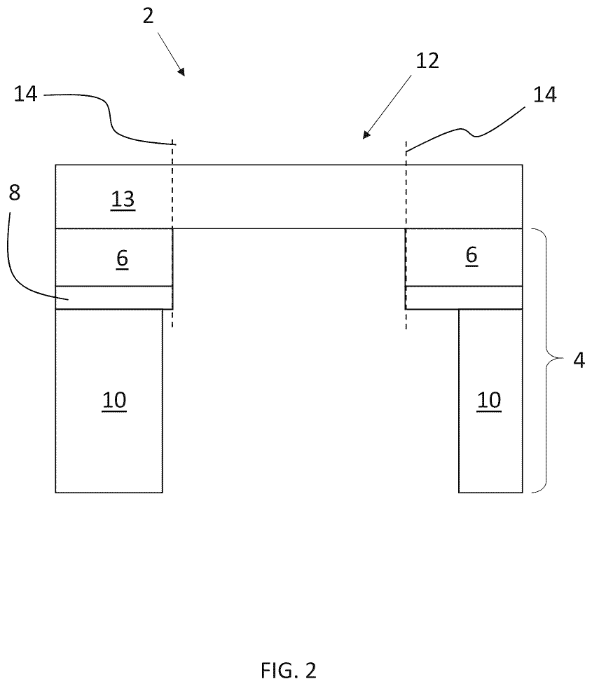

FIG. 2 shows a membrane device 2 comprising a SOI substrate 4. Similar or equivalent features in different figures have been given the same reference numerals to aid understanding and are not intended to limit the illustrated embodiments. Unlike in FIG. 1, the membrane 12 coincides with the nominal membrane area. The membrane etch from the back is still offset, but the BOX layer 8 has been locally removed before the membrane etch and is used as an etch mask that defines the membrane area. FIG. 2 shows a cross section of the membrane device 2, and the shape of the membrane 12 is typically circular with a membrane diameter. Other shapes of the membrane 12, such as rectangular with a width and a length, are also possible.

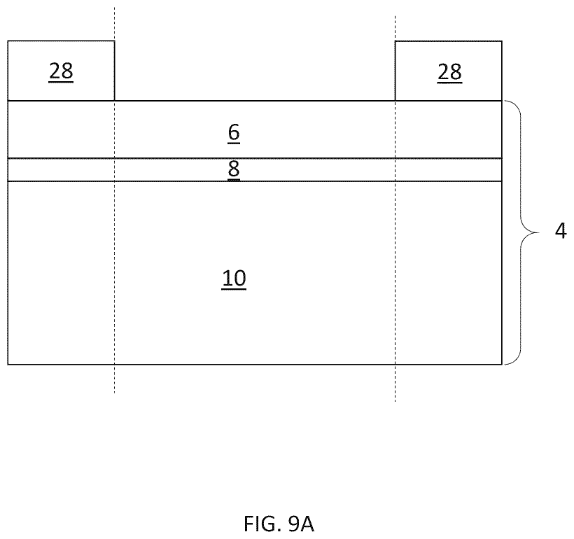

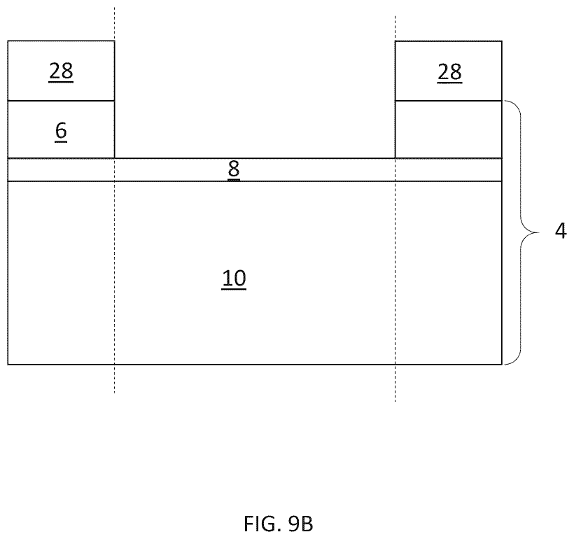

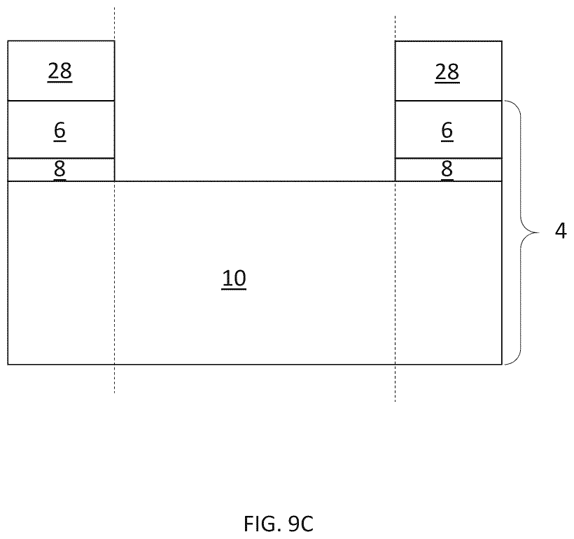

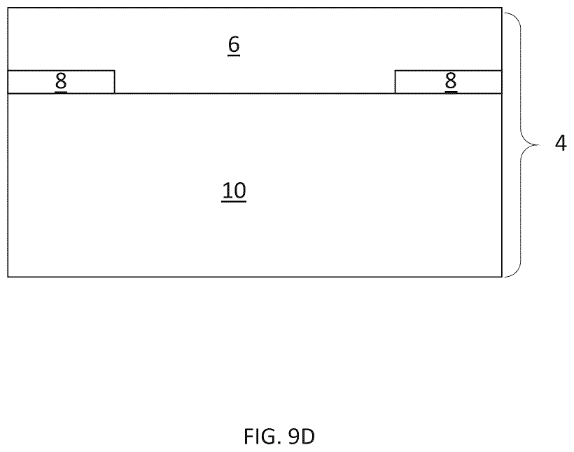

The BOX layer 8 can be removed precisely from the front side, for example using the handle wafer contact (HWC) module (being a module comprising a series of steps, such as the steps shown in FIGS. 9A to 9D below for example) in a complementary metal oxide semiconductor (CMOS) process. The HWC module can be used when processing a SOI substrate in order to create small contact areas between the active silicon layer 6 and the underlying handle wafer 10. The HWC module has been used when making high voltage (HV) devices, in order to change the breakdown behaviour across the BOX layer 8. The HWC module is applied at the start of the CMOS process, before the active silicon layer 6 is populated (i.e. before the active silicon layer 6 is doped to make semiconductor devices) and before the back end of line (BEOL) processing, whereby the active silicon layer 6 is covered by one or more metal layers for providing electrical connections to the active silicon layer 6 and dielectric layers for isolating and separating the metal layers. The HWC module typically comprises two etch steps followed by an epitaxial silicon growth step, and provides an opening in the BOX layer 8 so that the active silicon layer 6 is in direct contact with the handle wafer 10 in the opening. To make the illustrated membrane device 2, the HWC module is used to make a much larger opening that defines the membrane area. The HWC module does not need to be adapted and can still be used if making one or more HV transistors on the substrate 4 as well.

Since the BOX layer 8 has been locally removed in the membrane area, a single anisotropic etch that is silicon selective can be used to form the membrane 12. That is, unlike in the making of the device illustrated in FIG. 1, the etch does not have to be changed after reaching the BOX layer 8 to remove the silicon dioxide and then changed again to etch through the active silicon layer 6. Instead, a single etch (e.g. DRIE, deep reactive ion etching) can be used to etch all the way through both the handle wafer 10 and the active silicon layer 6. The etch stops on the membrane 12 comprising one or more dielectric layers (e.g. oxide). In one embodiment, the membrane 12 comprises a metal layer, which can be used as the etch stop layer. In this case, an SiO₂ etch is performed after the Si etch, which may therefore be less advantageous.

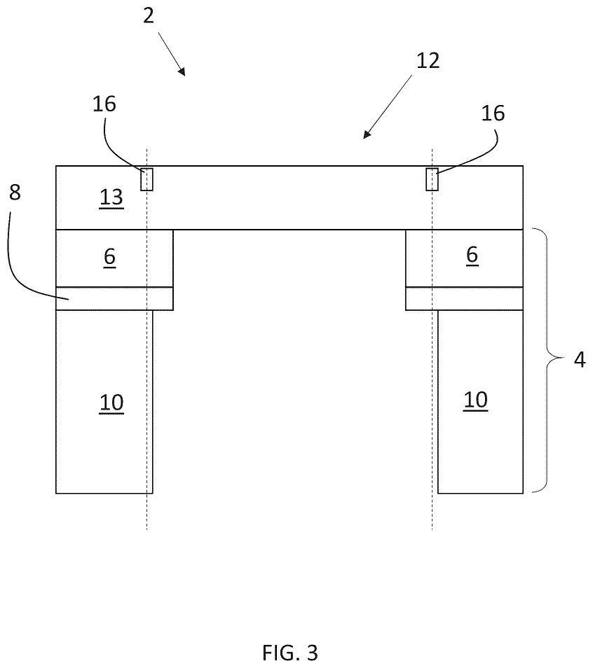

The membrane device 2 may also comprise reference markers to align the membrane etch (i.e. to align an etch mask on the back). FIG. 3 illustrates a membrane device 2 comprising two metal structures 16 being reference markers for aligning a membrane etch mask (not shown). The metal structures 16 may comprise parts of a patterned metal top layer formed in the BEOL process of a CMOS process. The position of a membrane etch mask relative to the nominal membrane area may be determined by optically scanning the front of the wafer. For example, an etching tool (for providing/applying the membrane etch mask and performing the etch) may be fixed in position relative to an optical scanner. The substrate 4 can then be placed between the optical scanner and the etching tool. The substrate 4 is then moved relative to the optical scanner and the reference markers detected from reflections. By aligning the reference markers relative to the optical scanner on the front side, the substrate 4 is also aligned to the etching tool on the back side.

The metal structures 16 are located on either side of the membrane 12, so as not to interfere with or impede the flexing of the membrane when in use.

Using reference markers can increase the accuracy of the position of the etch mask, which in turn can allow for a smaller etch foot print to be used.

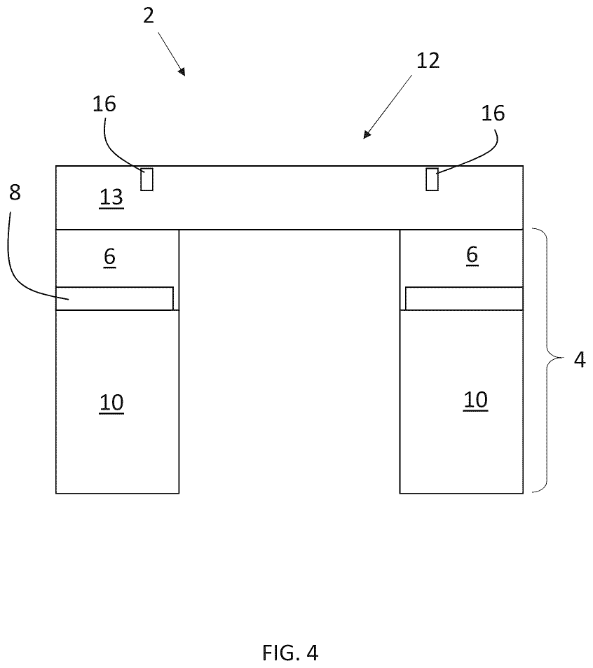

FIG. 4 shows an alternative embodiment, wherein the etch mask (not shown) defines the membrane area, which is smaller than the opening in the BOX layer 8. In this embodiment, the accuracy of the position of the final membrane 12, provided by using the reference markers 16 to position the membrane etch mask, may be sufficient, such that the membrane etch mask can be used on its own to define the membrane area instead of the (patterned) BOX layer 8. This embodiment has still has the benefit of only requiring one membrane etching step to form the membrane. For example, a single DRIE can be used to etch through the handle wafer 10 and the active silicon layer 6 to the membrane 12. Another potential advantage is that there is no edge/ledge between the BOX layer 8 and the handle wafer 10 (as there is in the embodiment of FIGS. 2 and 3).

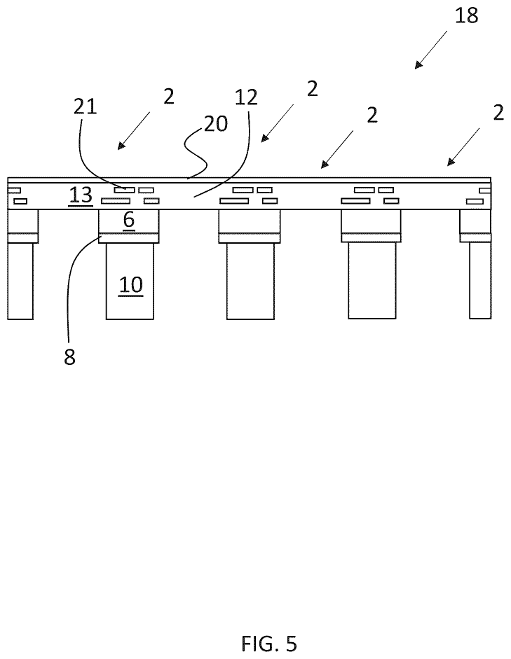

FIG. 5 shows a schematic cross-sectional diagram of an apparatus 18 comprising multiple membrane devices 2 in an array. The apparatus 18 may comprise any one of the membrane devices illustrated in FIGS. 2 to 4. Each membrane device 2 is formed at the same time. The apparatus 18 may be a micromechanical systems device (MEMS) array. For example, the apparatus 18 may comprise an actuation layer 20, such as a piezoelectric layer, for actuating the membranes 12 of the devices 2. For example, the apparatus 18 may be an ultrasonic transducer, a micro pump, a pressure sensor etc. In between membranes 12 of the devices, metal layers 21 are located between the dielectric layers 13 to provide electrical connections to the membrane devices 2.

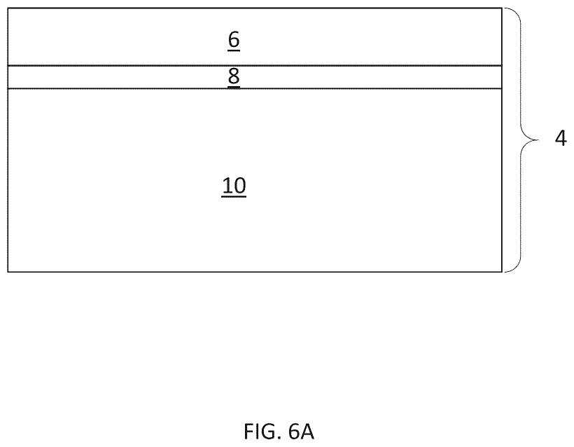

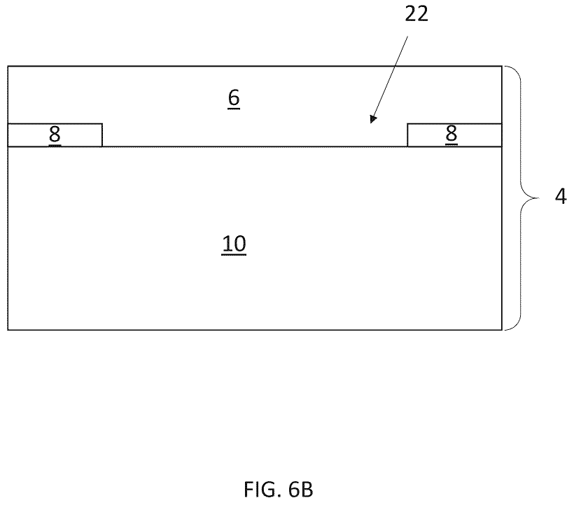

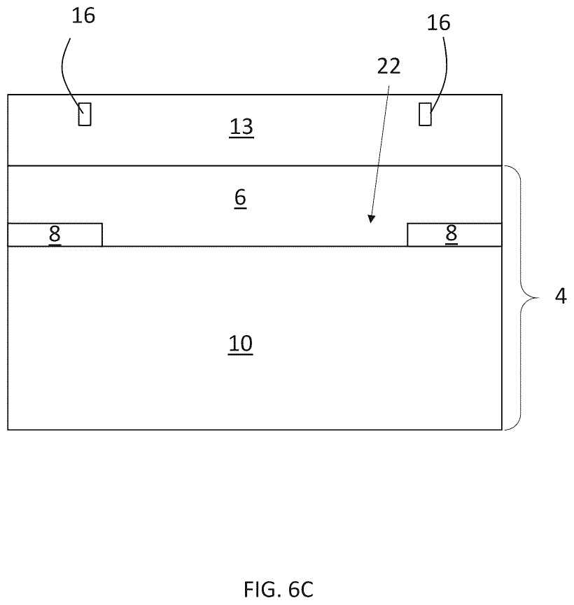

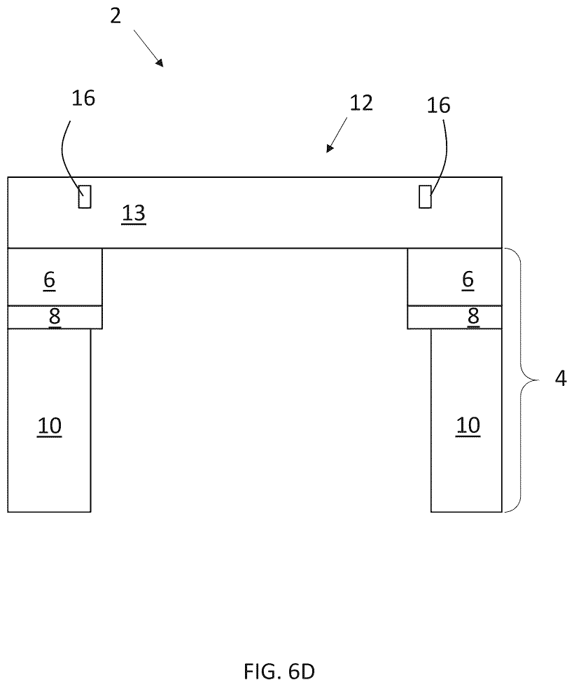

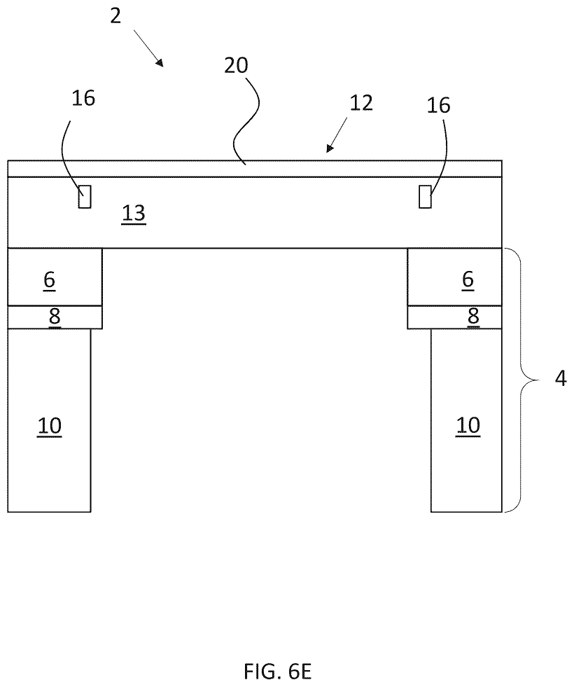

FIGS. 6A to 6E illustrate some steps of a method of making a membrane device. For example, the method may be used to form the membrane device 2 described in relation to FIG. 2.

FIG. 6A shows a SOI substrate 4 (also referred to as SOI wafer) comprising an active silicon layer 6, a BOX layer 8 and a handle wafer 10.

FIG. 6B shows the SOI substrate 4 after removing a part of the BOX layer 8 to create an opening 22 where the active silicon layer 6 is in contact with the handle wafer 10. The opening 22 may be round or square or some other shape and may have a diameter or width of at least 30 μm. For example, the method may be used to provide an opening 22 having a width in the range of 30 μm to 200 μm. The part of the BOX layer 8 may be removed using the HWC module of a CMOS process.

FIG. 6C shows the SOI substrate 4 after forming a plurality of dielectric layers 13 on the active silicon layer 6. The dielectric layers 13 may be comprised by a CMOS backend stack comprising metallization for connecting to the active silicon layer 6 to form semiconductor devices (e.g. transistors, diodes etc.). Two reference markers 16 are formed in (or between) the dielectric layers 13. The reference markers 16 are formed on either side of the opening 22 in the BOX layer 8. That is, the reference markers 16 do not overlap the opening 22. The reference markers 16 are usable for positioning an etch mask on the back (on the handle wafer 10). The reference markers 16 may be formed by depositing a metal layer on one of the dielectric layers 13 and patterning the metal layer to form metal structures that can be used as reference markers. The metal layer may be the top metal layer of a CMOS backend stack.

FIG. 6D shows a membrane device 2 comprising membrane 12 formed by etching from the back. The etching comprises an anisotropic etch through the handle wafer 10, through the opening 22 and through the active silicon layer 6. The etching is anisotropic and has a high selectivity for silicon. The etch area (defined by an opening in the membrane etch mask) is greater than the opening 22 and covers the whole opening 22. Therefore, the remaining BOX layer 8 restricts the width of the etch through the active silicon layer 6, as the etch stops on the BOX layer 8 in the etch area that does not overlap the opening 22 in the BOX layer 8. The plurality of dielectric layers acts as an etch stop layer for the active silicon layer 6. The etching is typically DRIE. The etch mask is positioned using the reference markers 16. A small offset of the etch mask relative to the substrate 4 does not affect the final membrane 12, which is still laterally defined by the opening 22 in the BOX layer 8.

FIG. 6E shows the membrane device after providing an actuation layer 20 (e.g. a piezoelectric layer), for actuating the membrane to cause bending in the membrane.

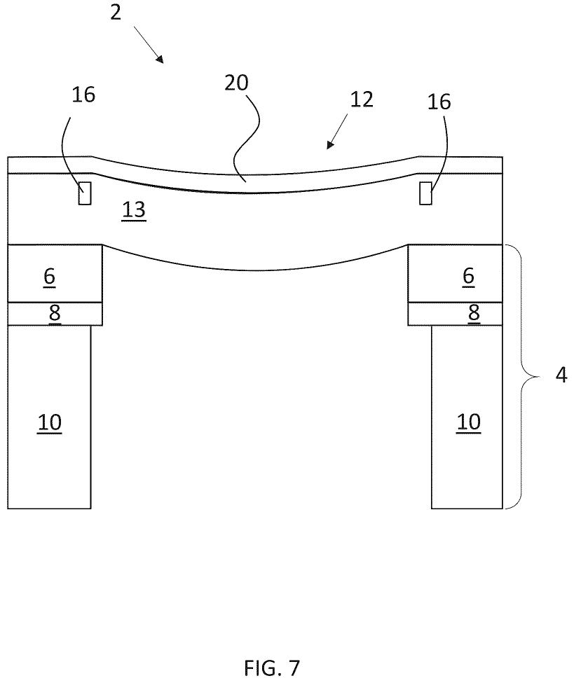

FIG. 7 shows a schematic cross section of a membrane device 2 in use. A voltage is applied across the actuation layer 20, causing the actuation layer to deflect the membrane 12.

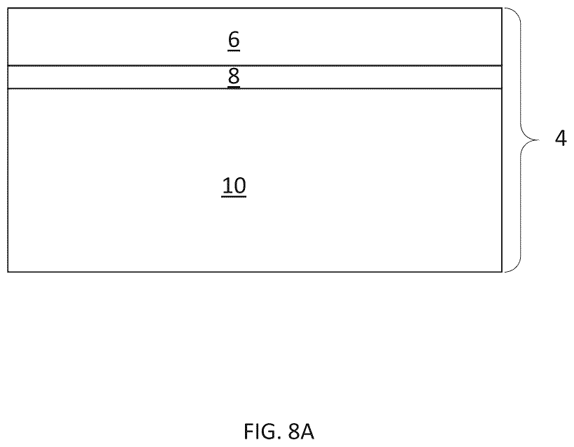

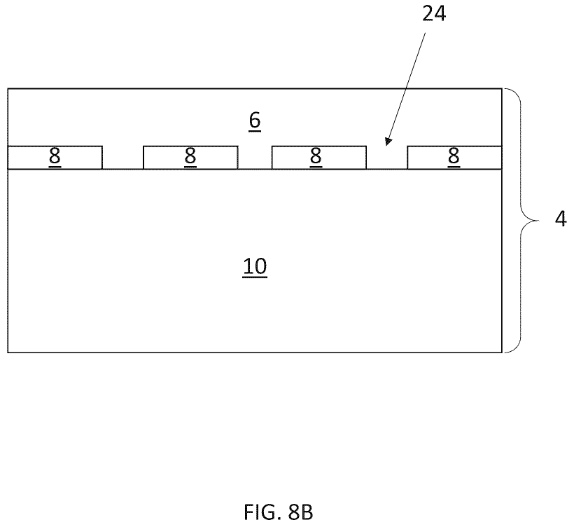

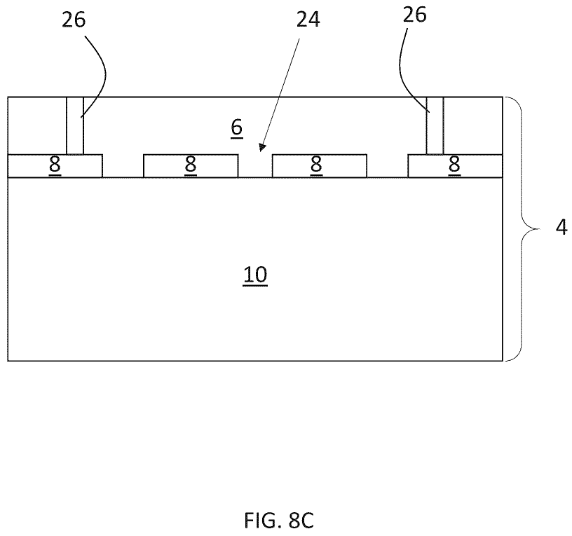

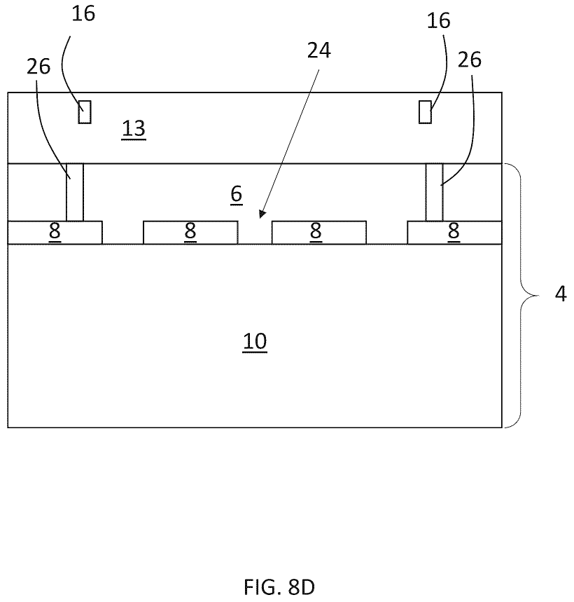

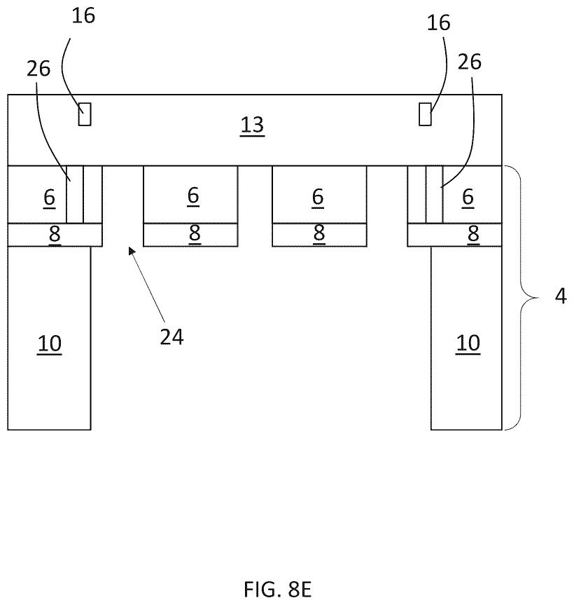

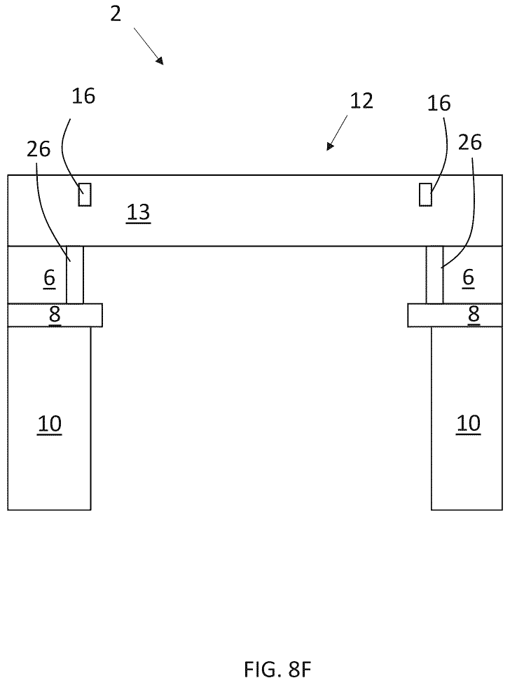

FIGS. 8A to 8F illustrate the steps of a method of making a membrane device. The method comprises two consecutive etch steps to release the membrane 12. The method may be particularly suitable for making membrane devices with large membranes (e.g. having a width or diameter >100 μm).

FIG. 8A shows a SOI substrate 4 (also referred to as SOI wafer) comprising an active silicon layer 6, a BOX layer 8 and a handle wafer 10.

FIG. 8B shows the SOI substrate 4 after removing a part of the BOX layer 8 to create a plurality of openings 24 where the active silicon layer 6 is in contact with the handle wafer 10. The part of the BOX layer 8 may be removed using the HWC module of a CMOS process. The plurality of openings 24 are located in the membrane area, where the membrane is going to be formed.

FIG. 8C shows the substrate 4 after forming isolation structure 26 in the active silicon layer 6. The isolation structure 26 may comprise deep trench isolation (DTI). The isolation structure 26 may be a circular wall that encloses the membrane area. The isolations structure 26 extends from an upper surface of the active silicon layer 6 to the BOX layer 8.

FIG. 8D shows the SOI substrate 4 after forming a plurality of dielectric layers 13 on the active silicon layer 6. The dielectric layers 13 may be comprised by a CMOS backend stack comprising metallization for connecting to the active silicon layer 6 to form semiconductor devices (e.g. transistors, diodes etc.). Two reference markers 16 are formed in (or between) the dielectric layers 13. The reference markers 16 are formed on either side of the isolation structure 26. The reference markers 16 are used for positioning an etch mask on the back (on the handle wafer 10). The reference markers 16 may be formed by depositing a metal layer on one of the dielectric layers 13 and patterning the metal layer to form metal structures that can be used as reference markers. The metal layer may be the top metal layer of a CMOS backend stack.

FIG. 8E shows the structure after etching from the back. The etching comprises an anisotropic etch through the handle wafer 10, through the openings 24 and through the active silicon layer 6 in areas that are exposed by the openings 24. The etching is anisotropic and has a high selectivity for silicon. The etch area (defined by an opening in the membrane etch mask) covers the openings 24. The plurality of dielectric layers acts as an etch stop layer. The etching is typically DRIE. The etch mask is positioned using the reference markers 16. Other methods of aligning the etch mask may alternatively be used.

FIG. 8F shows the membrane device 2 after an isotropic etch step. The isotropic etch removes the remaining active silicon in active silicon layer 6 in the membrane area and thereby releases the membrane 12. The openings 24 in the BOX layer 8 allows the etchant to penetrate into and remove the active silicon layer 6 in the membrane area. The isolation structure 26 acts as a lateral etch stopping layer and defines the lateral membrane dimensions.

FIGS. 9A to 9D show the steps of a part of a method of forming a membrane device. For example, the method may be used to form the membrane device described in relation to FIGS. 2, 3 and 4 above. FIGS. 9A to 9D illustrate a part of the method where a part of the BOX layer 8 is removed to make an opening 22 that defines the membrane area. The illustrated steps may be performed by the HWC module of a CMOS process.

FIG. 9A shows the SOI substrate 4 after applying an etch mask 28 on the active silicon layer 6. In FIG. 9B a first etch step has been performed to remove a part of the active silicon layer 6 that is exposed by the etch mask 28. The first etch stops on the BOX layer 8. In FIG. 9C, a second etch step is performed to remove the BOX layer 8 that is exposed by the etch mask 28 and thereby create an opening 22. The second etch exposes a part of the handle wafer 10. After locally removing the BOX layer 8, the etch mask 28 is removed and silicon is epitaxially grown on the handle wafer 10 to provide the structure shown in FIG. 9D.

In general, embodiments described herein provide a method of forming a membrane of a semiconductor membrane device, the method comprising providing a silicon on insulator (SOI) substrate comprising an active silicon layer, a buried oxide (BOX) layer, and a handle wafer, determining a membrane area of the substrate. The method further comprises locally removing the BOX layer in at least a part of the membrane area, providing one or more dielectric layers on the active silicon layer, and etching the substrate to form the membrane comprising the one or more dielectric layers in the membrane area, wherein the etching comprises an anisotropic etch through the handle wafer and the active silicon layer using an etch mask defining an etch area, wherein the etch area overlaps at least a part of the membrane area.

The etch area can be greater than the membrane area and overlaps a whole of the membrane area. Since the opening in the BOX layer can be used to define the lateral dimensions of the membrane when etching, the etch area can be larger, which can increase the allowed tolerance on the alignment of the etch mask without affecting the membrane properties. Typically, the membrane area and the etch area are substantially concentric. The membrane may be substantially circular or may have a rectangular shape for example.

The method may also comprise providing a metal layer before or during the step of providing the one or more dielectric layers. The metal layer can be used as the etch stop layer (to stop the anisotropic etch after going through the active silicon layer), and may form part of the final membrane.

Typically, the anisotropic etch is a deep reactive ion etch (DRIE). The etch needs to be sufficiently deep the go through the entire thickness of the handle wafer, which may be >400 μm. The BOX layer can be removed in a whole of the membrane area or may be removed in parts of the membrane area to provide a plurality of openings in the membrane area.

The etching step may further comprise an isotropic etch to remove silicon comprised by the active silicon layer in the membrane area. An isolation structure formed from the front can be used to stop the etch, and thereby define the lateral dimensions of the membrane. For example, the method may further comprise a step of deep trench isolation (DTI) to form an oxide barrier in the active silicon layer around the membrane area, wherein the oxide barrier stops the isotropic etch.

The method may further comprise depositing a piezoelectric layer on the one or more dielectric layers and covering the membrane area. The piezoelectric layer can be used to deflect the membrane.

The step of locally removing the BOX layer may comprise:
applying a mask with an opening defining the membrane area;
etching through the active silicon layer and the BOX layer to the handle wafer.

The etching typically comprises two separate etch steps for removing the active silicon layer and the BOX layer respectively. The same etch mask can be used for both etch steps.

The step of locally removing the BOX layer may be part of a complementary metal oxide semiconductor (CMOS) process for providing contact between the handle wafer and the active silicon layer. This part of the CMOS process may be performed using the handle wafer contact (HWC) module. After removing the BOX layer, the method may comprises providing epitaxial silicon directly on the handle wafer in the membrane area. In one embodiment, a SOI wafer for MEMS only may be used.

The method may further comprise forming one or more reference markers on or in the one or more dielectric layers, and using the reference markers to align the etch mask before the step of etching. The one or more reference markers may comprise one or more metal structures, and the step of forming the one or more reference markers may comprise depositing a metal layer on one of the one or more dielectric layers and patterning the metal layer.

The step of providing one or more dielectric layers may be comprised by a complementary metal oxide semiconductor (CMOS) back end of line (BEOL) process.

While specific embodiments of the invention have been described above, it will be appreciated that the invention may be practiced otherwise than as described. The descriptions above are intended to be illustrative, not limiting. It will be apparent to one skilled in the art that modifications may be made to the invention as described without departing from the scope of the claims set out below.

Each feature disclosed or illustrated in the present specification may be incorporated in the invention, whether alone or in any appropriate combination with any other feature disclosed or illustrated herein

1. A method of forming a membrane of a semiconductor membrane device, the method comprising:
providing a silicon on insulator (SOI) substrate comprising an active silicon layer, a buried oxide (BOX) layer, and a handle wafer;
determining a membrane area of said substrate;
locally removing said BOX layer in at least a part of said membrane area;
providing one or more dielectric layers on said active silicon layer; and
etching said substrate to form said membrane comprising said one or more dielectric layers in said membrane area, wherein said etching comprises an anisotropic etch through said handle wafer and said active silicon layer using an etch mask defining an etch area, wherein said etch area overlaps at least a part of said membrane area.

2. The method of claim 1, wherein said etch area is greater than said membrane area and overlaps a whole of said membrane area.

3. The method of claim 1, wherein said anisotropic etch is a deep reactive ion etch (DRIE).

4. The method of claim 1, wherein said step of locally removing said BOX layer comprises removing said BOX layer in a whole of said membrane area.

5. The method of claim 1, wherein said step of locally removing said BOX layer comprises removing said BOX layer from a part of said membrane area, and wherein said step of etching further comprises an isotropic etch to remove silicon comprised by said active silicon layer in said membrane area.

6. The method of claim 5, further comprising deep trench isolation (DTI) to form a oxide barrier in said active silicon layer around said membrane area, wherein said oxide barrier stops said isotropic etch.

7. The method of claim 1, wherein said membrane area and said etch area are substantially concentric.

8. The method of claim 1, further comprising depositing a piezoelectric layer on said one or more dielectric layers and covering said membrane area.

9. The method of claim 1, wherein said step of locally removing said BOX layer comprises:
applying a mask with an opening defining said membrane area; and
etching through said active silicon layer and said BOX layer to said handle wafer.

10. The method of claim 9, wherein said etching comprises two separate etch steps for removing said active silicon layer and said BOX layer respectively.

11. The method of claim 1, wherein said step of locally removing said BOX layer is part of a complementary metal oxide semiconductor (CMOS) process for providing contact between said handle wafer and said active silicon layer.

12. The method of claim 9, further comprising providing epitaxial silicon directly on said handle wafer in said membrane area.

13. The method of claim 1, further comprising forming one or more reference markers on or in said one or more dielectric layers, and using said reference markers to align said etch mask before said step of etching.

14. The method of claim 13, wherein said one or more reference markers comprise one or more metal structures, and wherein said step of forming said one or more reference markers comprises depositing a metal layer on one of said one or more dielectric layers and patterning said metal layer.

15. The method of claim 1, wherein said step of providing one or more dielectric layers is comprised by a complementary metal oxide semiconductor (CMOS) back end of line (BEOL) process.
